(19) United States
(12) Patent Application Publication
(10) Pub. No.: US 2016/0336062 A1
(43) Pub. Date: Nov. 17, 2016

(54) ACCESSING A RESISTIVE STORAGE ELEMENT-BASED MEMORY CELL ARRAY

(71) Applicant: HEWLETT PACKARD ENTERPRISE DEVELOPMENT LP, Houston, TX (US)

(72) Inventor: Brent E. BUCHANAN, Fort Collins, CO (US)

(21) Appl. No.: 15/111,185

(22) PCT Filed: Jan. 31, 2014
(86) PCT No.: PCT/US14/14055

§ 371 Date: Jul. 13, 2016

(51) Int. Cl. G11C 13/00; G11C 11/16

(52) U.S. Cl. CPC G11C 13/004; G11C 13/0004; G11C 13/003; G11C 11/1673

(57) ABSTRACT

A technique includes reading a row of memory cells of a memory cell array, where each of the memory cells includes comprising a resistive storage element and is associated with a column line. The technique includes, in association with the reading, coupling the column lines to a ground connection.

### BACKGROUND

Semiconductor memory devices typically are used in a computer system for purposes of storing data related to the various operations of the system. The memory device may be packaged as a unit in a semiconductor package to form a “memory chip,” and several such chips may be assembled together in the form of a module (a dual inline memory module (DIMM), for example), such that several modules may form, for example, the system memory of the computer system.

A computer system has traditionally contained both volatile and non-volatile storage devices. In this manner, due to their relatively faster access times, volatile memory devices, such as dynamic random access memory (DRAM) devices, have traditionally been used to form the working memory for the computer system. To preserve computer system data when the system is powered off, data has traditionally been stored in non-volatile mass storage devices associated with slower access times, such as magnetic media-based or optical media-based mass storage devices.

The development of relatively high density, solid state non-volatile memory technologies is closing the gap between the two technologies, and as such, non-volatile memory devices are becoming increasingly used to form a working, persistent memory for both traditional “memory” and “storage” functions.

### BRIEF DESCRIPTION OF THE DRAWINGS

FIG. 1 is a schematic diagram of a computer system according to an example implementation.

FIG. 2 is a schematic diagram of a memory device of the computer system of FIG. 1 according to an example implementation.

FIG. 3A is an illustration of programming a resistive storage element to have a low resistance state (LRS) according to an example implementation.

FIG. 3B is an illustration of programming a resistive storage element to have a high resistance state (HRS) according to an example implementation.

FIG. 4 is a schematic diagram of a memory cell array according to an example implementation.

FIGS. 5, 6 and 7 are illustrations of voltages applied to row and column lines of the memory cell array to read a row of memory cells according to example implementations.

FIG. 8 is a schematic diagram of a memory cell array illustrating the use of operational amplifiers to sense memory cell values and establish virtual grounds according to an example implementation.

FIG. 9 is a schematic diagram illustrating the use of a current mirror circuit to detect a value stored in a memory cell and provide a virtual ground according to an example implementation.

FIG. 10 is a schematic diagram of a memory cell array using current mirror circuits to establish virtual grounds and read values stored in a selected row of memory cells according to an example implementation.

FIG. 11 is a flow diagram depicting a technique to read values stored in a row of memory cells according to an example implementation.

### DETAILED DESCRIPTION

One type of memory cell uses a resistive storage element to store a value for the cell. In this context, a “resistive storage element” generally refers to a non-volatile element whose resistance indicates a stored value and which may be read or sensed (via a current, for example) to retrieve the stored value. Moreover, the state of the element may be changed/programmed via the voltage to cause the element to have a certain resistance and correspondingly set the value that is stored by the element. A bipolar Memristor cell, or resistive random access memory (RRAM) cell, is one example of such a resistive storage element, as further described herein. However, the systems and techniques that are disclosed herein may be used with other resistive storage elements, such as a unipolar RRAM cell, a phase change random access memory cell (PCRAM), a magnetoresistive random access memory cell (MRAM), and so forth.

Techniques and systems are disclosed herein for purposes of reading resistive storage element-based memory cells of a memory cell array in a manner that reduces, if not eliminates “sneak” currents, which are non-ideal currents that exist in the non-selected memory cells. More specifically, techniques and systems are disclosed herein for purposes of reading an entire row of resistive storage element-based memory cells at one time, and coupling column lines of the selected cells to a common, fixed potential (a potential other than ground, ground, or a virtual ground, as examples).

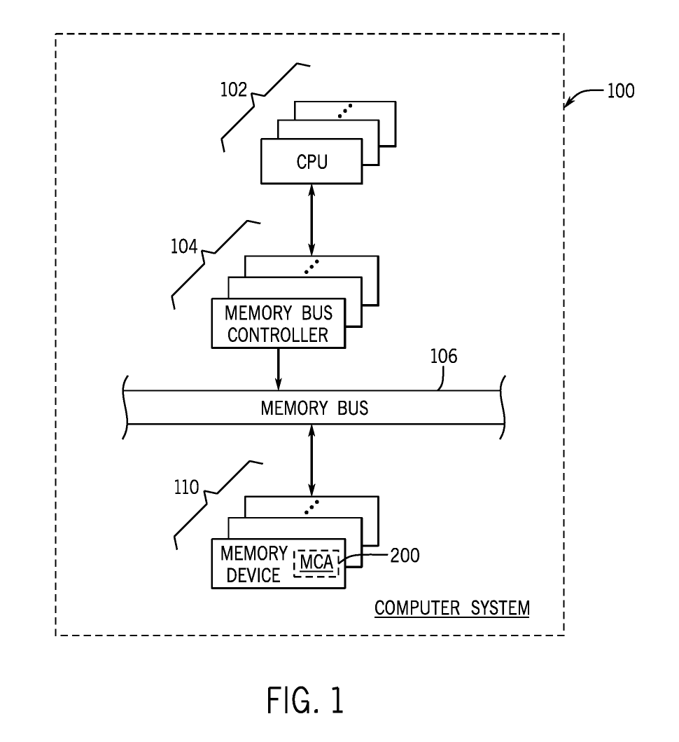

Referring to FIG. 1, a memory cell array 200 that is formed from resistive storage elements may form part of a memory device 110 of a computer system 100 that is generally illustrated in FIG. 1. Referring to FIG. 1, the computer system 100 is a physical machine that is made up of actual hardware and actual software (i.e., machine executable instructions). In this regard, the computer system 100 may include one or multiple central processing units (CPUs); and each CPU 102 may include one or multiple processing cores. In this regard, the CPU 102 may be packaged inside a particular semiconductor package, which is constructed to be mechanically and electrically mounted to a motherboard of the computer system 100 via an associated connector, or socket. In this manner, the socket may be constructed to receive at least a portion of this semiconductor package, which contains the package's electrical contacts, and the socket has mechanical features to secure the semiconductor package to the socket. As a more specific example, in accordance with example implementations, the CPU 102 may be contained in a surface mount package, which has a land grid array (LGA) for purposes of forming electrical connections with corresponding pins of the receiving socket. Other semiconductor packages may be employed, in accordance with further example implementations.

As further depicted in FIG. 1, the computer system 100 may include one or multiple memory controllers 104. In this manner, in accordance with example implementations, one or multiple memory controllers 104 may be integrated into a given CPU 102 to allow processing core(s) of the CPU 102 to access one or multiple memory modules of the computer system 100 via a memory bus 106. Each memory module may include one or more of the memory devices 110.

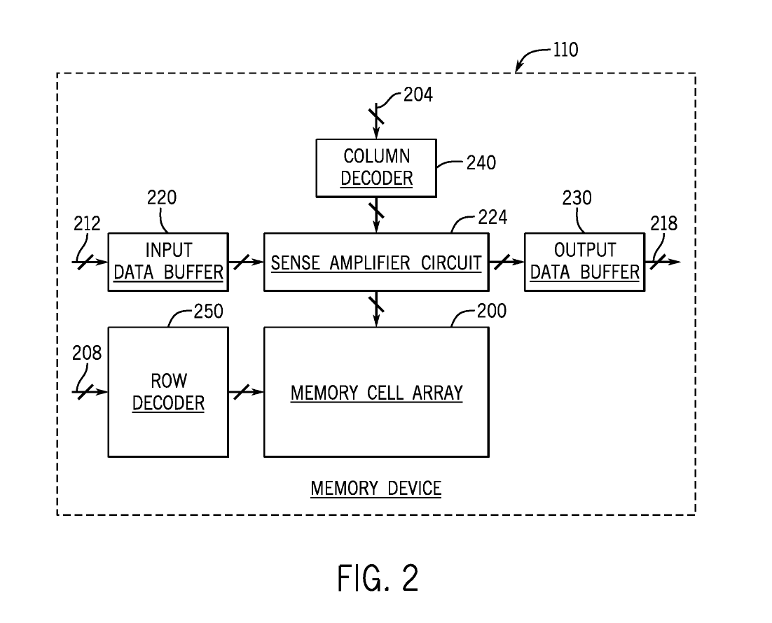

Referring to FIGS. 2 and 4, the memory cell array 200, in accordance with example implementations, is a crosspoint array that includes row lines 400 and column lines 404. The array 200 includes memory cells 300 that are associated with the intersections of the row and column lines. In this manner, in general, a given memory cell 300 of the memory cell array 200 may be accessed (for purposes of reading a value from the cell or writing a value to the cell) by the row and column line pair that corresponds to the cell 300.

A targeted set of memory cells for a given memory operation is selected by column and row address signals that are received by the memory device 110. Referring to FIG. 2, in general, the memory device 110 includes a column decoder 240, which receives column address signals at its input terminals 204 in connection with targeted memory cells and decodes these signals to generate signals to select the corresponding column lines 404 of the memory cell array 200. The memory device 110 further includes a row decoder 250, which decodes row address signals at its input terminals 208 to generate signals to select the appropriate row line 400 of the memory cell array 200. For this purpose, the row decoder 250 may serve as a control circuit, which generates the appropriate read voltage for selected row line 400, and couples unselected row lines 400 to fixed, non-read potentials or allows these unselected row lines 400 to float, as further described herein.

As depicted in FIG. 2, the memory device 110 further includes an input data buffer 220, which receives input data (via input terminals 212) associated with write operations. In accordance with example implementations, for a write operation, the input data may be communicated to a sense amplifier circuit 224 of the memory device 110, which generates the appropriate programming voltages on memory cells that are targeted by the write operation for purposes of writing values to the cells 300. For a read operation, the sense amplifier circuit 224 senses values stored in the memory cells 300 that are targeted by the read operation to form corresponding values that are stored in an output data buffer 230. In this manner, the read data may be retrieved from output terminals 218 of the output data buffer 230.

It is noted that the memory device architecture of FIG. 2 is merely a simplified example of example components of the memory device 110, as the memory device 110 may have other architectures and other components, in accordance with further implementations.

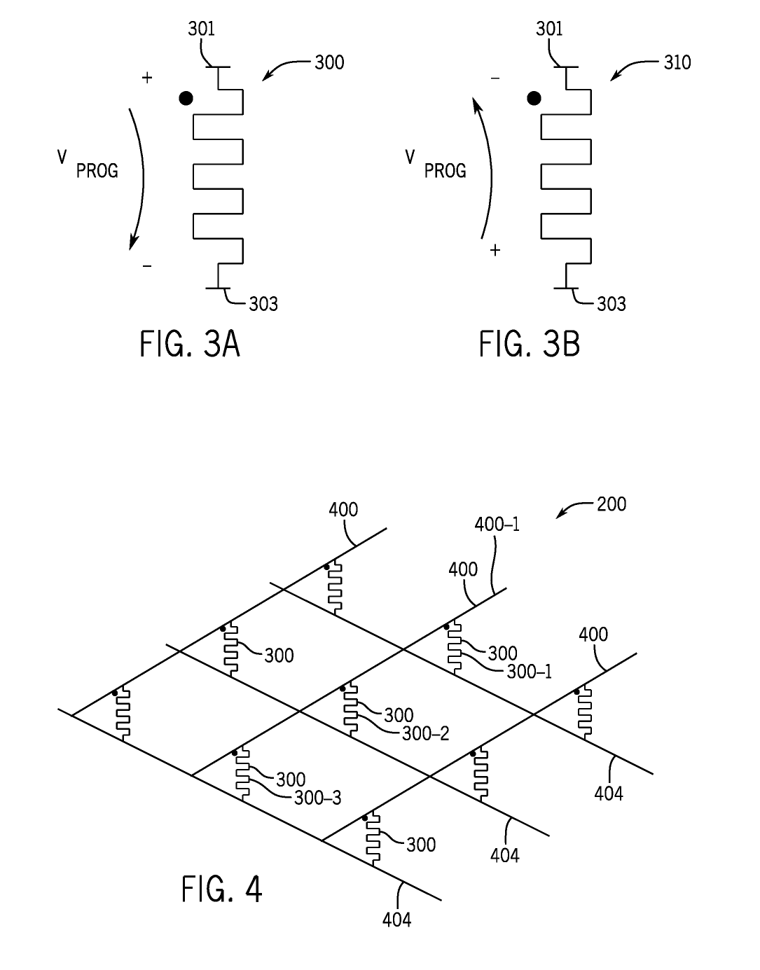

In accordance with example implementations, the memory cell 300 is formed from a resistive storage element, which is coupled between (and thus, selected or addressed by the activation of) a row line 400 and column line 404 (see FIG. 4). In general, the resistive storage element has a resistance, which indicates a corresponding stored value (a logic one or logic zero, for example) for the memory cell 300. FIGS. 3A and 3B illustrate the programming of resistance states for the memory cell 300, in accordance with example implementations. The resistive storage element may be programmed to exhibit either a low resistance state (LRS) by applying a positive programming voltage (called “V_{PROG}”) between top 301 and bottom 303 electrodes of the resistive storage element (as illustrated in FIG. 3A) or exhibit a high resistance state (HRS) by applying a negative V_{PROG} programming voltage between the top 301 and bottom 303 electrodes (as illustrated in FIG. 3B). The absolute magnitude of the V_{PROG} programming voltage may be higher than the absolute magnitude of a read voltage, which may be applied in either direction across the resistive storage element for purposes of sensing the element's resistance (i.e., sensing whether the element is in the LRS or in the HRS), i.e., for purposes of reading the value that is stored by the memory cell 300.

For purposes of achieving a relatively high density memory product, memory cells 300 constructed from the programmable resistive elements may be arranged in a crosspoint array, such as the array 200 of FIG. 4. One of the characteristics of a crosspoint array is that when a read or write voltage is applied to targeted or selected cells of the array, some of this voltage may also appear across a significant number of non-selected memory cells. These “partially selected” cells conduct respective currents called “sneak” currents, and the sneak currents may interfere with the operation of the selected cells by, for example, burning excess power beyond the power intended for the read/write operation; masking the signal from the selected cell during read operations; slowing the signal to/from the selected cell as the sneak path resistor-capacitor (R-C) charges/discharges; and so forth. Moreover, the sneak currents may cause an electric field to be applied across the unselected cells, thereby potentially disturbing the contents of the cells.

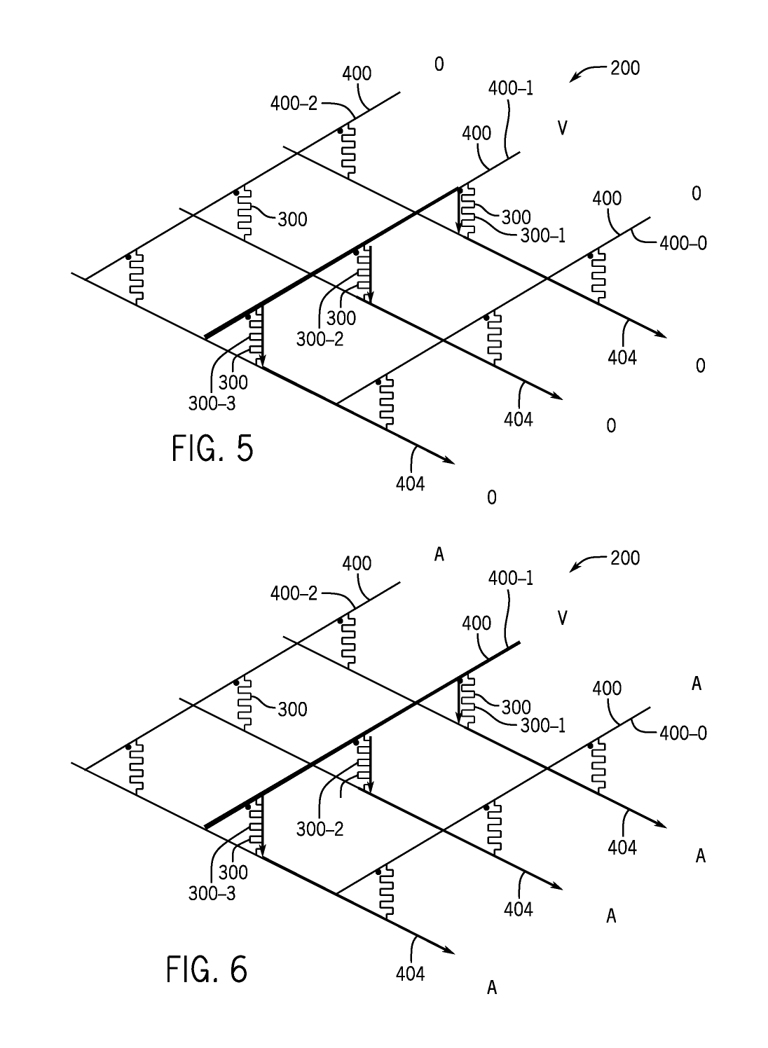

Systems and techniques are disclosed herein for purposes of reducing, if not eliminating, sneak currents during read operations. More specifically, in accordance with example implementations, entire rows of the memory cell array 200 are read simultaneously so that the current in the associated row line conductor is fully utilized. In this manner, FIG. 5 illustrates the reading of a row of memory cells 300, in accordance with example implementations. For this example, row line 400-1 is selected so that the memory cells 300 associated with the selected row line 400-1 are read. As illustrated in FIG. 5, for this purpose, the row line 400-1 receives a read voltage called “V,” in FIG. 5; and the unselected row lines 400, as well as the column lines 404 are coupled to a zero potential, or ground (denoted by the “0”). As described further herein, currents in the selected memory cells 300 may be sensed while the read voltage is being applied for purposes of sensing the values stored in these cells 300.

By setting the column lines and unselected row lines all to zero volts or all to some identical non-zero voltage, no sneak current exists in the cells 300 of the unselected rows during the read operation. This means that sense amplifiers that are coupled to the column lines 404 for purposes of detecting/sensing the stored values also maintain respective grounds while reading the cell states.

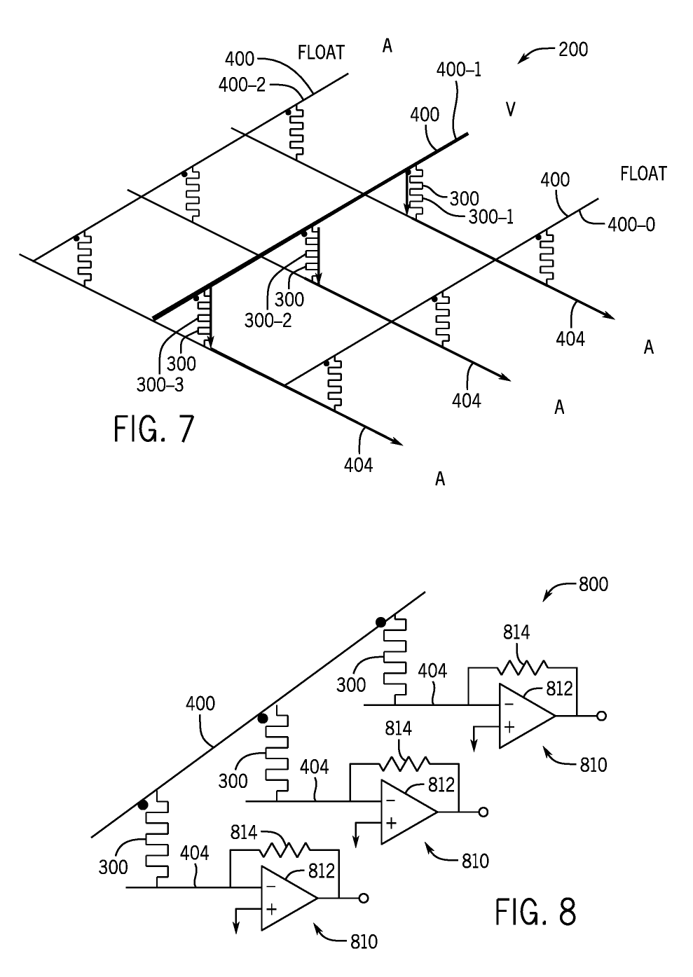

FIG. 6 illustrates another technique that may be used to read a row of the memory cells 300, in accordance with further implementations. For this technique, the unselected row line 400 and column lines 404 are held to the same fixed potential (not necessarily zero volts), as represented by the “A,” voltage of FIG. 6. Moreover, referring to FIG. 7, in yet further example implementations, for purposes of reading a row of the memory cells, the column lines 404 may be set to the A potential, while the unselected row lines 400 are allowed to float (i.e., the unselected row lines 400 are neither coupled to ground or to any fixed potential, as depicted in FIG. 7. This is because there is little to no voltage difference across the relevant column conductors.

In accordance with example implementations, column lines 404 may be coupled to respective virtual grounds. In this manner, referring to FIG. 8, in accordance with example implementations, the columns lines 404 may be coupled to operational amplifiers-based circuits 810, as illustrated in FIG. 8. In this regard, a given column line 404 may be coupled to a virtual ground that is established by an associated amplifier circuit 810 for the column line 404, and the virtual ground is created by the input terminal of an operational amplifier 810. More specifically, for this example, the operational amplifier 812 is used to form an inverting amplifier circuit, in which the non-inverting input terminal of the operational amplifier 812 is coupled to ground; and the inverting and output terminals of the operational amplifier 812 are coupled together via a feedback resistor 814.

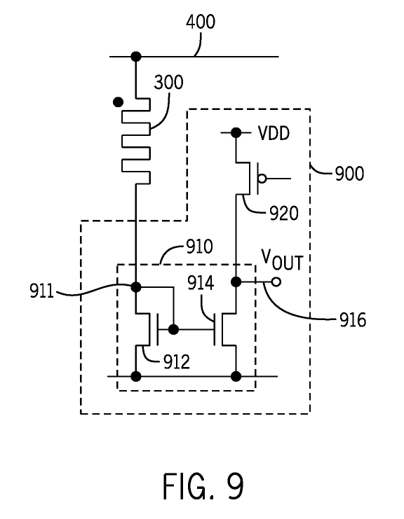

For example implementations in which the column lines are connected to a fixed potential (see FIG. 7), a current mirror-based amplifier 900 of FIG. 9 may be used. Referring to FIG. 9, the amplifier 900 includes a current mirror 910 that is coupled to the column line 404. In this regard, the current mirror 910 includes an n-channel metal-oxide-semiconductor field-effect-transistor (nMOSFET) 912 which is configured to function as a “MOSFET diode” to couple the column line 404 to a relatively small potential (a voltage less than 1 volt, for example).

In this regard, the column line 404 is coupled to the drain of the nMOSFET 912, with the drain of the nMOSFET 912 being coupled to its gate terminal and the source of the nMOSFET 912 being coupled to ground. To form the current mirror, another nMOSFET 914 has its gate terminal coupled to the gate terminal of the nMOSFET 912, with the source of the nMOSFET 914 being coupled to ground and the drain of the nMOSFET 914 providing an output signal (called “Vₒᵤₜ” in FIG. 9) at an output node 916 for the amplifier 900. As shown in FIG. 9, a pull up p-channel MOSFET (pMOSFET) 920 is coupled between the node 916 and a voltage supply rail (called “V_{DD},” in FIG. 9). In this regard, the source-to-drain path of the pMOSFET 920 is coupled between the V_{DD} supply rail and the node 916, with the gate of the pMOSFET 920 receiving a bias voltage.

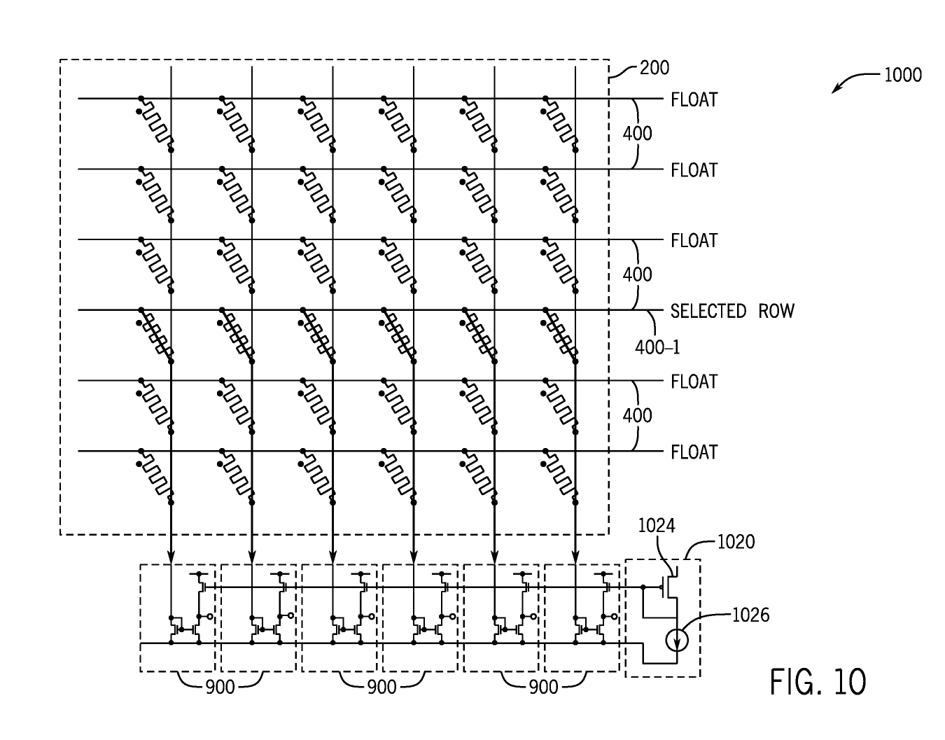

FIG. 10 is an illustration 1000 depicting the use of the amplifiers 900 with the memory cell array 200, in accordance with example implementations. Referring to FIG. 10, multiple sense amplifiers 900 are coupled to the column lines 404. In this manner, the nodes 916 of the amplifiers 900 provide voltages indicative of the respective values stored in the selected memory cells of the row. As an example, the gate terminals of the pMOSFETs may be coupled to a bias circuit 1020. For this example, bias circuit 1020 mirrors a bias current (called “I_{BIAS},” in FIG. 10) in each of the pMOSFETs 920. More specifically, the drain and gate terminals of the pMOSFET 1024 are coupled together, the source terminal of the pMOSFET 1024 is coupled to the V_{DD} supply rail, and the source-to-drain path of the pMOSFET 1024 communicates the I_{BIAS} current (i.e., shown as being serially coupled to an I_{BIAS} current source 1026).

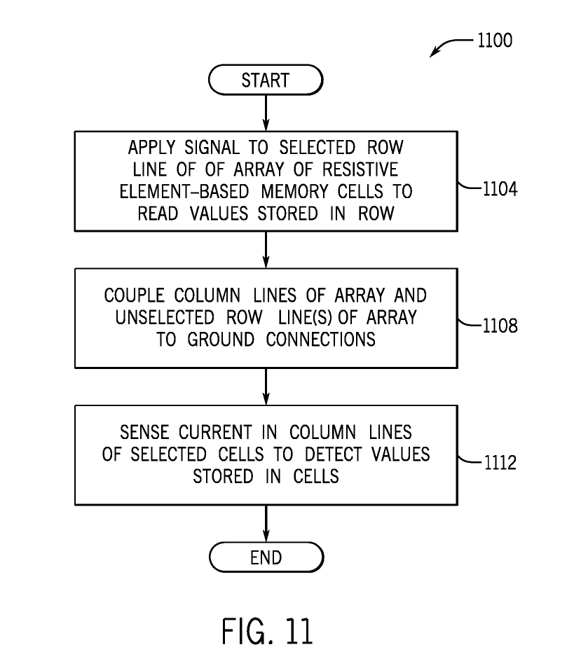

Thus, referring to FIG. 11, in accordance with example implementations, a technique 1100 includes applying (block 1104) a signal to select a row line of an array of resistive element-based memory cells to read values stored in the cells. The technique 1100 includes coupling (block 1108) column lines of the array to a fixed potential (a potential of ground, near ground, a fixed potential or virtual ground, for examples); and sensing (block 1112) currents in the column lines to detect values that are stored in the cells associated with the selected row line.

Among the advantages of the systems and techniques that are disclosed herein, sneak currents in crosspoint memory arrays that employ resistive elements may be significantly mitigated, if not eliminated; power may be saved; memory access times may be reduced; read margins may be improved; and operations of unselected cells may not be disturbed during read operations; as just a few examples. Other and different advantages are contemplated, which are within the scope of the appended claims.

While the present invention has been described with respect to a limited number of embodiments, those skilled in the art, having the benefit of this disclosure, will appreciate numerous modifications and variations therefrom. It is intended that the appended claims cover all such modifications and variations as fall within the true spirit and scope of this present invention.

What is claimed is:

1. A method comprising:
reading a row of memory cells of a memory cell array, each of the memory cells comprising a resistive storage element and being associated with a column line; and
in association with the reading, coupling the column lines to a ground connection.

2. The method of claim 1, wherein coupling the column lines comprises coupling the column lines to an actual ground or to a virtual ground.

3. The method of claim 1, wherein coupling the column lines comprises coupling the column lines to a fixed potential to mitigate sneak currents.

4. The method of claim 1, further comprising:
in association with the reading, coupling unselected row lines of the memory cell array to a fixed potential.

5. The method of claim 1, further comprising:
in association with the reading, floating unselected row lines.

6. The method of claim 1, further comprising using at least one sense amplifier to enforce a virtual ground on at least one of the column lines.

7. The method of claim 1, wherein using the at least one sense amplifier comprises using an operational amplifier having a feedback path and using a current mirror.

8. An apparatus comprising:
a memory cell array comprising of a plurality of row lines, and resistive storage elements forming memory cells of the array;
a first circuit to apply a voltage to a given row line of the plurality of row lines of the array to read values from a subset of the memory cells associated with the given row line, wherein the memory cells of the subset are further associated with column lines; and
a second circuit to apply a ground connection to the column lines to mitigate sneak currents.

9. The apparatus of claim 8, wherein the second circuit causes a virtual ground or an actual ground to be coupled to the column lines.

10. The apparatus of claim 8, wherein the first circuit couples unselected row lines to a fixed potential.

11. The apparatus of claim 8, wherein the first circuit allows unselected row lines to float.

12. The apparatus of claim 8, wherein at least one of the memory cells comprises an RRAM cell, a PCRAM cell or an MRAM cell.

13. An apparatus comprising:
a plurality of row lines;
a plurality of column lines;
memory cells, each memory cell comprising a resistive storage element associated with one of the column lines of the plurality of column lines and one of the row lines of the plurality of column lines to form a crosspoint array for selecting the memory cells; and
sense amplifiers coupled to the column lines to sense values stored by the memory cells in response to a given row line of the row lines associated with the cells being selected in a read operation and couple the column lines to ground connection.

14. The apparatus of claim 13, wherein the sense amplifiers coupled the column lines to a virtual ground or an actual ground.

15. The apparatus of claim 13, further comprising a circuit to either couple unselected row lines to a fixed potential or allow the unselected row lines to float.
